(19) United States
(12) Patent Application Publication
(10) Pub. No.: US 2011/0242885 A1
(43) Pub. Date: Oct. 6, 2011

(54) THREE-DIMENSIONAL PHASE CHANGE MEMORY

(75) Inventor: Jin-Ki Kim, Ottawa (CA)

(73) Assignee: MOSAID TECHNOLOGIES INCORPORATED, Ottawa (CA)

(21) Appl. No.: 13/079,795

(22) Filed: Apr. 4, 2011

Related U.S. Application Data
(60) Provisional application No. 61/320,973, filed on Apr. 5, 2010.

(51) Int. Cl. G11C 11/00; H01L 21/8239

(52) U.S. Cl. 365/163; 438/382; 257/E21.004; 365/148

(57) ABSTRACT

A memory device includes a stack of semiconductor layers. A circuit is on a layer of the stack of semiconductor layers. A primary memory array is on another layer of the stack of semiconductor layers different from the layer comprising the circuit. A plurality of electrical communication paths are between the circuit and the primary memory array. The circuit controls the operation of the primary memory array over the electrical communication paths.

### CROSS-REFERENCE TO RELATED APPLICATIONS

This application is a utility application claiming priority U.S. Provisional Application Ser. No. 61/320,973 filed on Apr. 5, 2010 entitled “3-DIMENSIONAL PHASE CHANGE MEMORY,” the entirety of which is incorporated by reference herein.

### TECHNICAL FIELD

The present invention relates generally to semiconductor memory devices. More specifically, the present invention relates to a semiconductor memory device with three-dimensional integration.

### BACKGROUND

Phase change memories are nonvolatile memory devices storing data using phase change materials such as chalcogenide. A common chalcogenide compound is Ge₂—Sb₂—Te₅ (GST). These phase change materials are capable of stably transitioning between crystalline and amorphous phases by controlling heating and cooling processes. The amorphous phase exhibits a relatively high resistance compared to the crystalline phase, which exhibits a relatively low resistance. The amorphous state, also referred to as the RESET state or logic “0” state, is established by heating the GST compound above a melting temperature of 610° C., then rapidly cooling the compound. The crystalline state, also referred to as the SET state or logic “1” state is established by heating the GST compound above a crystallizing temperature of 450° C. but below the melting temperature of 610° C., and for a longer period of time sufficient to transform the material into the crystalline state, followed by a subsequent cooling period.

FIG. 1 shows a schematic of a typical phase change memory cell 10 comprising a storage element 12 and a switching element 14. The storage element is represented by a variable resistor whose value can be altered by transforming a structure between the crystalline and amorphous phases. The switching element 14 is used to selectively access the memory cell 10.

FIG. 2 shows a phase change memory cell storage element 20 with a heater 22 between a bottom electrode 24 and a Chalcogenide compound 26. The Chalcogenide compound 26 is contacted by a top electrode 28, typically with low resistance. Similarly, the bottom electrode 24 is used to make a low resistance contact to the heater 22. The heater 22 transforms a portion of the Chalcogenide compound 26 from the crystalline state to an amorphous state (shown) within a physical space referred to here as the programmable volume 29.

FIG. 3 is a graph showing the relationship of temperature versus time for both RESET and SET programming of a phase change memory as shown in FIG. 2. The phase change cell can be programmed to the amorphous or RESET state by heating the phase change layer to a temperature T_Reset with a current I_Reset through the heater for a duration equal to tP_Reset, then quickly cooling down the phase change layer. Similarly, the phase change cell can be programmed to the crystalline or SET state by heating the phase change layer to a temperature T_set with a current I_Set through the heater and maintaining the phase change layer at temperature T_Set for a duration equal to tP_Set, and then cooling down the phase change layer, where tP_Set exceeds tP_Reset. Also, shown are current pulses for writing RESET and SET states 32 and 34.

Phase change materials are thermally activated. The phase change memory cell is programmed to the SET state by applying a current I_Set for a duration equal to tP_Set. The amount of heat “J” applied to the phase change layer is proportional to I²×R, where “I” is a magnitude of a current I_Set through the heater and “R” is a resistance of the heater. While the memory cell is being programmed to the SET state, the phase change layer is changed to a crystalline state, resulting in a lower cell resistance compared to the RESET state as shown in FIG. 4. Similarly the phase change memory cell is programmed to the RESET state by applying a current I_Reset for a duration equal to tP_Reset. While the memory cell is being programmed to the RESET state, a certain volume of phase change layer is changed to the amorphous state, resulting in a higher cell resistance than the SET state. The programmable volume in a phase change layer is generally a function of “J”.

Phase change memory devices typically use the amorphous state to represent a logical “0” state (or RESET state) and the crystalline state to represent a logical “1” state (or SET state). Table 1 summarizes typical phase change memory properties.

TABLE 1
Phase Change Memory Properties

| Data | “0” | “1” |
|---|---|---|
| Program State | Reset | Set |
| Resistance | High (>100K) | Low (10K) |
| Read Current | Low | High |
| Material Phase | Amorphous | Crystalline |
| Write Pulse | ~50 ns | ~200 ns |

In recent years, various phase change memory cells have used an MOS transistor 54 shown in FIG. 5, a bipolar transistor 64 shown in FIG. 6 or a diode 74 shown in FIG. 7, as the switching element in the memory cell in an attempt to reduce cell size and thereby improve memory density. Further improvements in memory system density are needed to continue to reduce memory system cost and increase memory capacity driven in part by increased data traffic in electronic systems.

### SUMMARY

In one aspect, the invention features a method of fabricating a memory device comprising forming a stack of semiconductor layers. A circuit is formed on a layer of the stack of semiconductor layers. A primary memory array is formed on another layer of the stack of semiconductor layers different from the layer comprising the circuit. A plurality of electrical communication paths are formed between the circuit and the primary memory array. The circuit controls the operation of the primary memory array over the electrical communication paths.

In another aspect, the invention features a memory device comprising a stack of semiconductor layers. A circuit is on a layer of the stack of semiconductor layers. A primary memory array is on another layer of the stack of semiconductor layers different from the layer comprising the circuit. A plurality of electrical communication paths are between the circuit and the primary memory array. The circuit controls the operation of the primary memory array over the electrical communication paths.

In another aspect, the invention features a memory device comprising a base semiconductor layer comprising a plurality of memory control circuits. A stack of semiconductor layers is formed over the base semiconductor layer. Each layer of the stack of semiconductor layers includes a memory array in communication with one of the plurality of memory control circuits.

### BRIEF DESCRIPTION OF THE DRAWINGS

The above and further advantages of this invention may be better understood by referring to the following description in conjunction with the accompanying drawings, in which like numerals indicate like structural elements and features in various figures. The drawings are not necessarily to scale, emphasis instead being placed upon illustrating the principles of the invention.

FIG. 1 is a schematic view of a phase change memory cell.

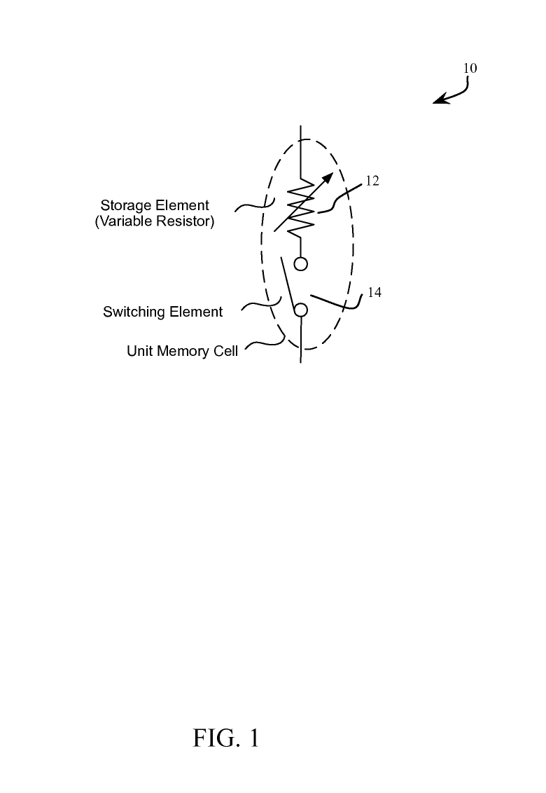

FIG. 2 is a cross-sectional view of a phase change memory cell storage element.

FIG. 3 is a graph of temperature change during a SET and a RESET operation of a conventional PCM cell.

FIG. 4 is a cross-sectional view of a phase change memory in the SET state and the RESET state.

FIG. 5 is a schematic view of a MOS transistor-based phase change memory cell.

FIG. 6 is a schematic view of a bipolar transistor-based phase change memory cell.

FIG. 7 is a schematic view of a diode-based phase change memory cell.

FIG. 8 is a cross-sectional view of a diode-based phase change memory.

FIG. 9 is a cross-sectional view of a three-dimensional diode-based phase change memory in accordance with an embodiment of the present invention.

FIG. 10 is a schematic view of a phase change memory array.

FIG. 11 is a schematic view of a phase change memory WRITE operation.

FIG. 12 is a schematic view of a phase change memory READ operation.

FIG. 13 is a block diagram of a three-dimensional phase change memory architecture in accordance with an embodiment of the present invention.

FIG. 14 is a block diagram of a three-dimensional phase change memory architecture with segmented arrays in accordance with an embodiment of the present invention.

FIG. 15 is a schematic view of a local column selector.

FIG. 16 is a schematic view of a global column selector.

FIG. 17 is a schematic view of a global column selector.

FIG. 18 is a schematic view of a WRITE driver circuit.

FIG. 19 is a schematic view of a sense amplifier circuit.

FIG. 20 is a schematic view of a row decoder circuit.

FIG. 21 is a timing diagram of the WRITE operation in accordance with an embodiment of the invention.

FIG. 22 is a timing diagram of the READ operation in accordance with an embodiment of the invention.

### DETAILED DESCRIPTION

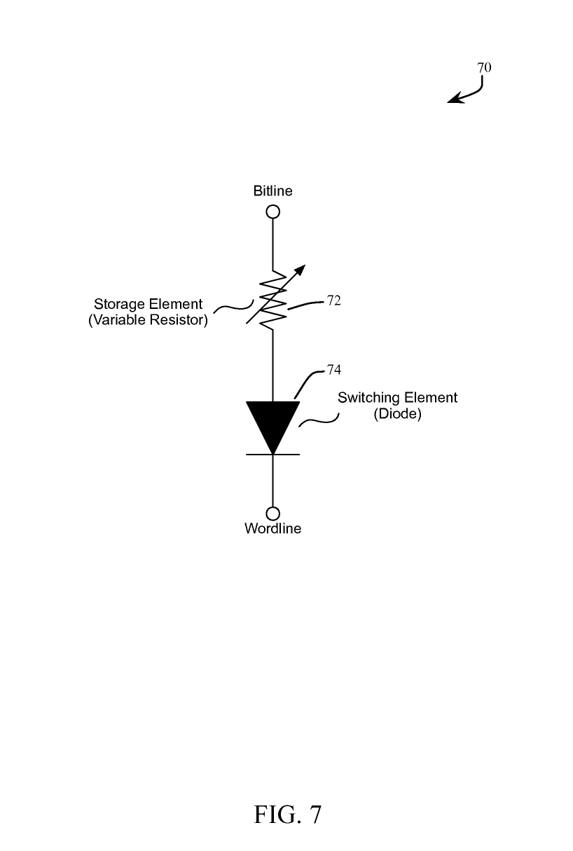

In one embodiment, a phase change memory cell uses a diode as the switching element as shown in FIG. 7. In other embodiments, the switching element is an MOS transistor or a bipolar transistor. In other embodiments, the memory device is an SRAM, a magneto resistive RAM (MRAM) or a ROM.

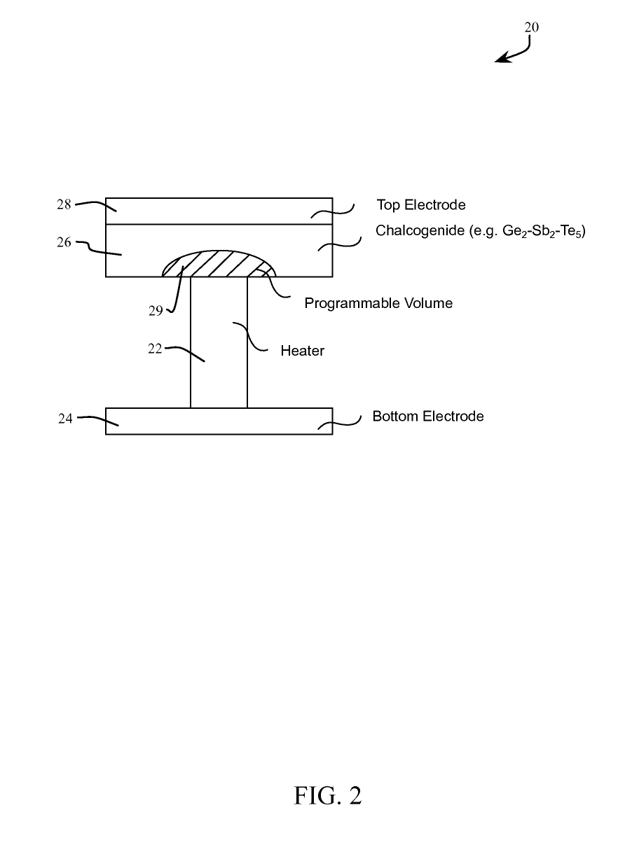

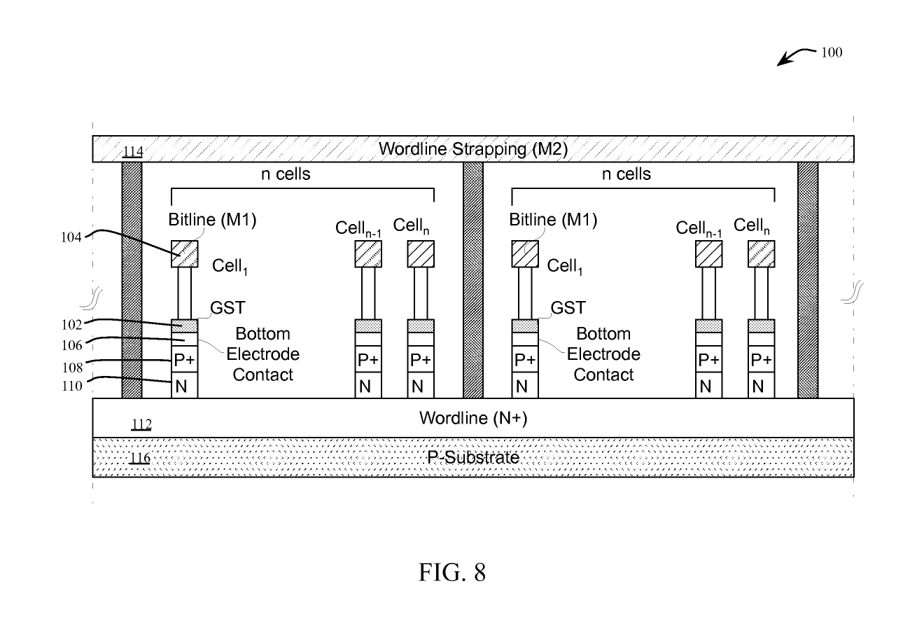

FIG. 8 shows a cross sectional view of a diode-based phase change memory according to an embodiment. Referring to FIG. 8, a top electrode 102 is connected to a bitline 104 formed by a first metal layer (M1). The bitline 104 communicates with circuitry (described below) to send data to and from the memory cells. Each memory cell is configured with a GST based storage element 102, which with reference to FIG. 2 includes a top electrode 28, a GST material 26 capable of stable transition between amorphous and crystalline phases and a heater 22. The heater 22 constricts current flow to elevate the temperature of the GST material 26, necessary in forming the programmable volume 29. The GST based storage element 102 further connects to a self-aligned bottom electrode 106, and a vertical P-N diode connected in series with anode 108 and cathode 110.

The cathode 110 is further connected to a wordline 112 formed in an N+ doped base in the semiconductor layer 116, in this example doped with a P-type dopant. In other examples, other dopant materials are used consistent with the formation of the memory cell diode. Specifically, FIG. 8 shows a “P+/N” diode where the N-doped cathode 110 connects to the N+ doped wordline 112. N+ doping results in lower resistance, which minimizes signal loss when circuitry (described below) provides a positive bias across the memory cell diode. Specifically, the cathode 110 is forced to a lower potential (or voltage) than the anode 108, by lowering the wordline 112 potential relative to the bitline 104, and thereby causing diode conduction and a “connection” between the GST based storage element 102 and the wordline 112. In other embodiments, an “N+/P” diode is used where the N+ anode connects to the self-aligned bottom electrode 106 and the P cathode connects to a P+ doped wordline with a reversal of the wordline 112 and bitline 104 potentials required to access the memory cell data. A wordline strap 114 uses the second metal layer (M2) to reduce the word line resistance. A wordline strap can be used for every n phase change memory (PCM) cells, n being an integer, for example, n is 256. The choice of how often to connect (e.g. “strap”) the wordline 112 with the low resistance strap 114 is made by strapping often enough to lower the word line resistance between a driver and the worse case memory cell (the cell furthest from the strap connection), but not strapping so often as to significantly increase the overall memory array size.

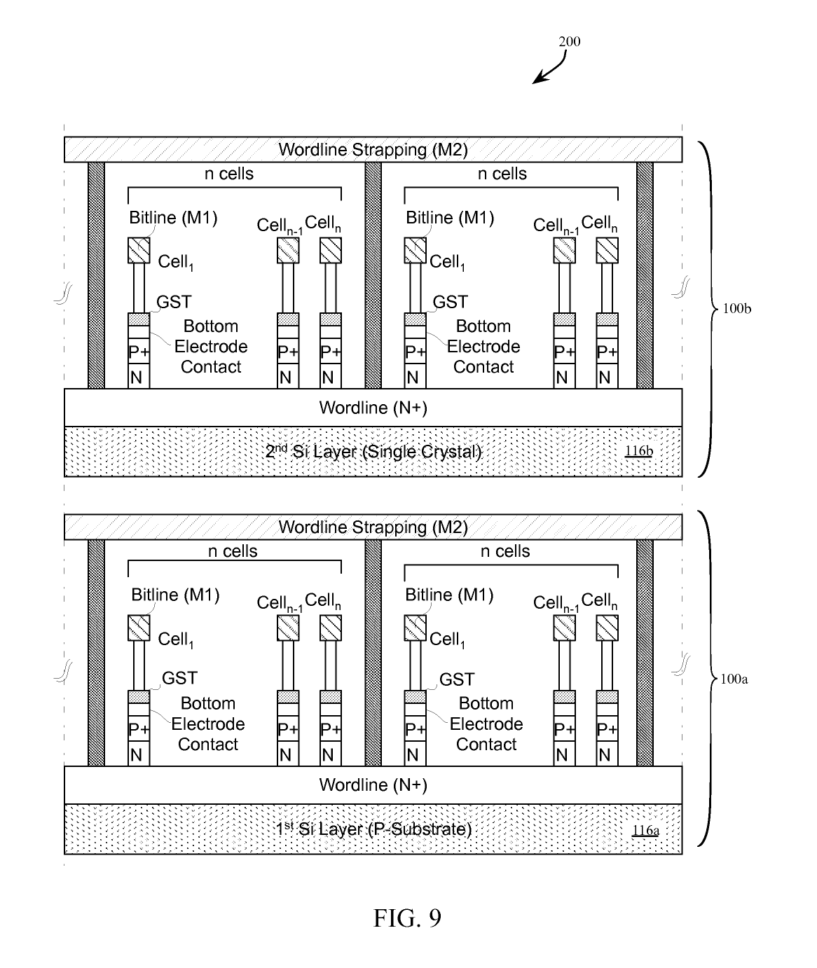

FIG. 9 shows a cross sectional view of a three-dimensional diode-based phase change memory in accordance with another embodiment. In FIG. 9, a three-dimensional PCM cell array is shown with two stacked PCM structures 100a and 100b. Any number of structures are envisioned within the scope of the invention. Stacking PCM structures provides numerous advantages including an improvement of memory footprint area for a given memory capacity (e.g. total number of memory bits or storage locations) by reducing the total plan-view area of an encapsulated silicon device. This in turn reduces the cost of a circuit board that the device is affixed to because the circuit board then requires fewer layers for routing and improves communication speed and quality between a PCM device and another device by reducing interconnect capacitive and resistive effects (e.g. “loading”). Stacked PCM structures also reduce the cost and improve communication speed and quality of the PCM device itself. By reducing the plan-view area of the first PCM structure 100a the fabrication yield is improved. Fabrication steps can also be simplified. In one example, the PCM structure 100a comprises the fabrication steps for making a PCM memory and transistor devices used to control the PCM memory, while the PCM structure 100b eliminates the steps for forming transistor devices.

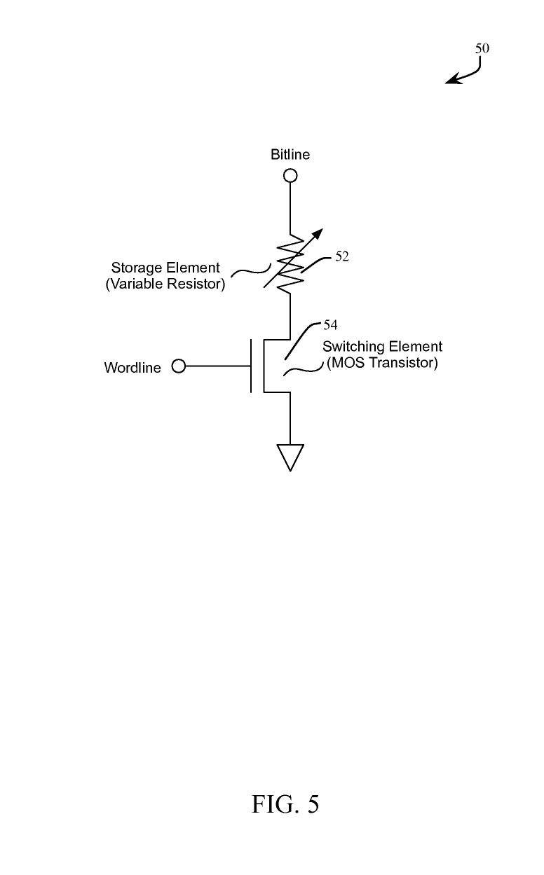

In one embodiment, the various PCM structures are formed to have different characteristics. For example, the PCM structure 100a can be formed to include decoding and sensing circuitry and the PCM memory cells associated with the PCM structure 100a have a row and column address mapping that provides faster communication speed. The PCM structure 100b (and structures overlying PCM structure 100b) are further removed from the decoding and sensing circuitry so will accordingly have slower communication speed. The communication speed between PCM memory cells and decoding and sensing speed is affected by signal loading on the wordline and bitlines and particularly varies with vertical communication paths between PCM structures 100a and 100b for example. The vertical communication can occur through “vias,” preferentially stacked vias. In addition to or separate from, providing different communication speed capabilities for one or more PCM structures, the PCM structures can have different PCM memory cell switching elements. For example, the PCM structure 100a can be formed with a MOS transistor switching element as shown in FIG. 5 preferentially with MOS transistor decoding, sensing and other circuitry on the same layer, while the PCM structure 100b can be formed with a diode switching element as shown in FIG. 7. This allows further customization of electrical performance for one or more PCM structures. Each of the PCM structures shown in FIG. 9 can be made with any one of the FET-based, bipolar-based or diode-based switching elements as shown in FIGS. 5, 6 and 7 respectively.

Silicon layers 116a and 116b are shown in FIG. 9. In another embodiment, one or more of the layers 116a, 116b and layers overlying layer 116b use semiconductor materials including GaAs and “III-V” compound materials. In the phase change memory, the PCM structures 100a and 100b have the same structure of the diode-based phase change memory as shown in FIG. 8. The first layer of the PCM cell array is fabricated on a P-substrate 116a (e.g. the first semiconductor layer). The second layer of the PCM cell array is fabricated on the second semiconductor layer 116b. Similarly, additional PCM structures are fabricated on layers formed over the PCM cell array 100b.

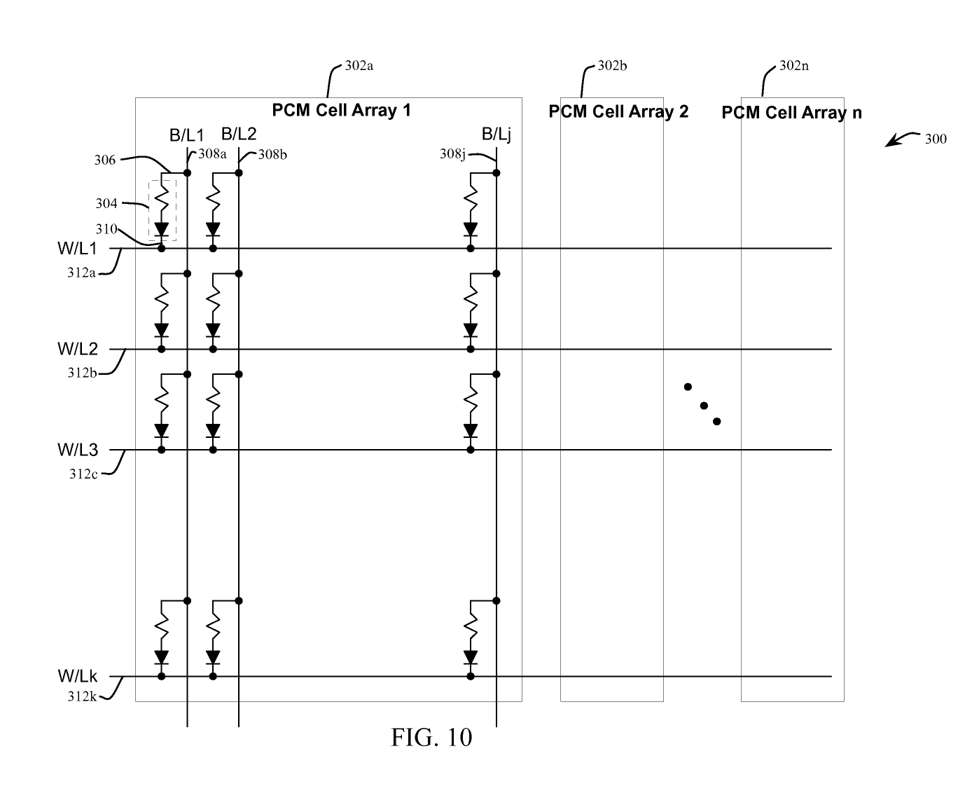

FIG. 10 shows a schematic view of a plurality of PCM cell arrays according to an embodiment. Referring to FIG. 10, each of a plurality of PCM cell arrays 302a through 302n (generally 302) is fabricated on a separate semiconductor layer (e.g. layers 116a and 116b in FIG. 9), in one example. In another example, more than one of the PCM cell arrays 302 are fabricated on the same layer. The PCM cell arrays 302 include a plurality of memory cells 304 with a first terminal (e.g. top electrode) 306 connected to a corresponding bit-line (B/L) 308a of a plurality of bit-lines 308a through 308j (generally 308). The memory cells 304 have a second terminal 310 connected to a corresponding word-line (W/L) 312a of a plurality of word-lines 312a through 312k (generally 312). Each of the plurality of PCM cell arrays 302 is connected to a plurality of bitlines 308 and wordlines 312. The bitlines 308 are arranged orthogonal to the wordlines 312 with each memory cell 304 forming a cross-point connection when the bitlines 308 and wordlines are appropriately biased to cause the switching element of the memory cell 304 to conduct. The bit-lines are also referred to as “columns” and the word-lines are referred to as “rows.” A data-word is stored and retrieved from the PCM cell arrays 302 by selecting a wordline 312 corresponding the location of all of the data-word and driving or sensing changes onto the bitlines 308 that correspond to the various bits of the data-word. A data-word can be stored in adjacent memory cells 304, which share a common wordline 312, in one example. In other examples, the data-word is stored in memory cells 304 that are not physically adjacent to provide “sparcity.” Sparcity reduces the peak current requirements of power supply busses that supply power to sensing and driving circuits. In another example, the data-word is comprised of memory cells 304 that are in one or more PCM cell arrays 302, either on the same PCM structure or on different PCM structures.

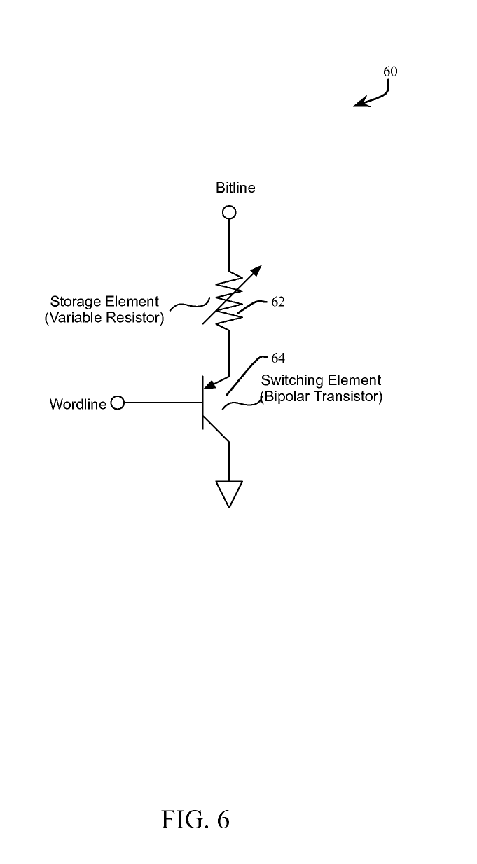

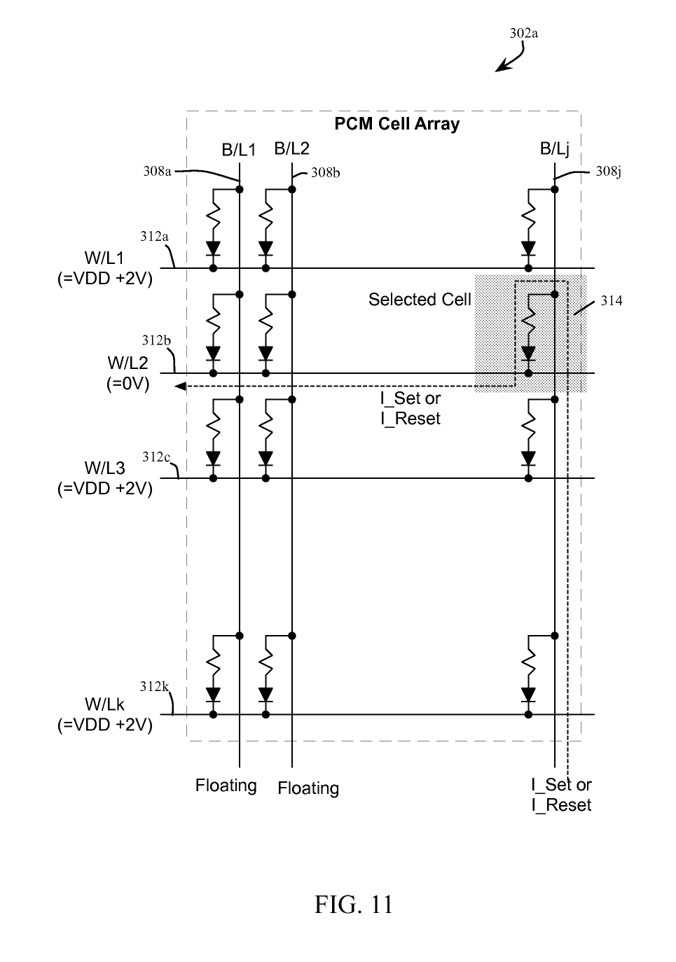

FIG. 11 shows the PCM cell array 302a in FIG. 10 with biasing for a WRITE operation. Referring to FIG. 11, the wordline 312b is selected by changing its bias to 0V, while the unselected wordlines 312a and 312c through 312k remain unselected with a bias of VDD+2V. In the particular example, VDD is 1.8V and the technology uses a 0.18 μm minimum feature size. However it should be understood that other voltages, process technologies and cell characteristics are comprehended within the scope of the invention. Write current with a value of either “I_Reset” or “I_Set” from a write driver (not shown) flows to the selected word-line 312b through a selected cell 314 and the selected bit-line 308j, while unselected bit-lines (e.g. 308a, 308b and others not shown) are left in a high impedance “floating” state, with the bit-line potential held up by the parasitic capacitance of the bit-line. Unselected cells connected to either an unselected word-line or a floating bit-line are reverse biased because the cathode of the diode switching element in each unselected memory cell is biased to a higher potential than the respective anode of the diode switching element, and thus no current flows through these unselected cells. More specifically, the diode switching elements in each unselected memory cell are reverse biased by 2V in the embodiment shown in FIG. 11. Although each diode will cease to conduct substantial current when the anode potential is at or below one diode threshold (typically 0.7V) of its cathode potential, the prevention of subthreshold current conduction requires a greater amount of reverse bias (e.g. 2V in this embodiment). The requirement to suppress subthreshold leakage of the unselected memory cells during a WRITE operation helps reduce spurious weak programming of unselected memory cells, thereby reducing the “signal margin” or the sensing voltage (or current) difference between the two programmed states. The issue of maintaining a wide sense margin is even more critical when the PCM memory cells are programmed to four different levels in a further adaptation to the embodiment shown in FIG. 11. Each of the PCM cell arrays 302 in FIG. 10 is biased for a WRITE operation in a similar manner to that described for PCM cell array 302a. A similar requirement to adequately reverse bias the unselected memory cells occurs with either the FET based or bipolar based switching element shown in FIGS. 5 and 6 respectively. In the case of a FET-based switching element, the gate to source potential must be well below the FET threshold including any body effects. In the case of the bipolar-based switching element the base-emitter diode must be adequately reverse biased to prevent conduction.

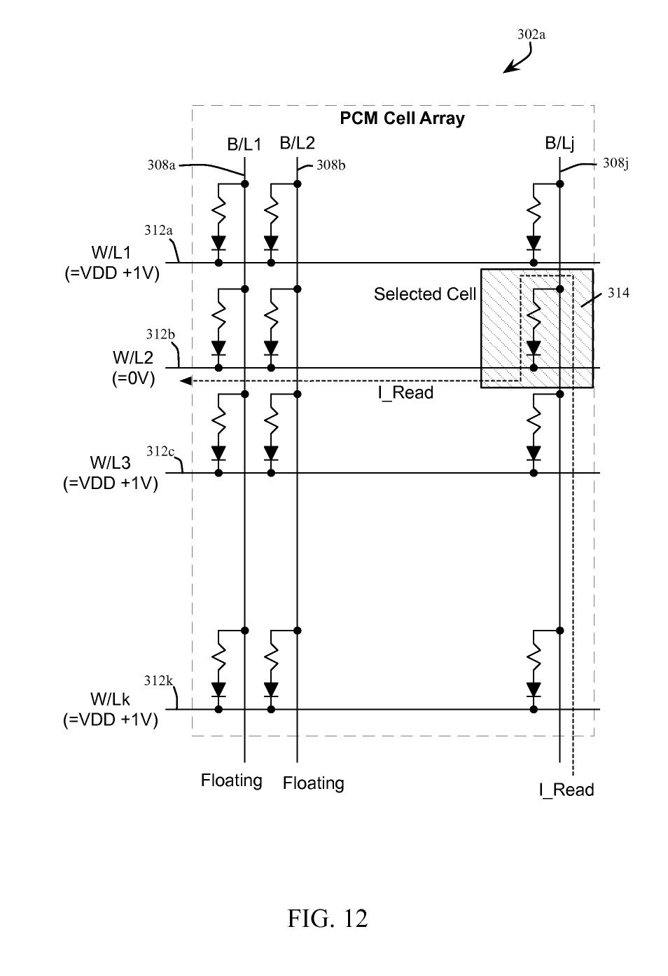

FIG. 12 shows the PCM cell array 302a of FIG. 10 biased for a READ operation. Referring to FIG. 12, word-line 312b is selected by changing its bias to 0V, while the unselected word-lines 312a and 312c through 312k remain unselected with a bias of VDD+1V. For example, VDD is 1.8V and the technology uses a 0.18 um minimum feature size. It should be understood that other voltages, process technologies and cell characteristics are comprehended in other embodiments. Read current “I_Read” from a sense amplifier (or “sense amp” (not shown)) flows to the selected word-line 312b through the selected cell 314 and the selected bit-line 308k, while unselected bit-lines (e.g. 308a, 308b and others not shown) are left in a high impedance “floating” state, with the bit-line potential held up by the parasitic capacitance of the bit-line. Unselected cells connected to either an unselected word-line or a floating bit-line are reverse biased and thus no current flows through these unselected cells. Each of the PCM cell arrays 302 in FIG. 10 is biased for a READ operation in a similar manner to that described for PCM cell array 302a. Similar to the WRITE case, unselected memory cells have their respective diode switching elements reverse biased beyond the level where substantial current flows and to a level required to suppress subthreshold leakage through each diode. The requirement to suppress subthreshold leakage of each of the unselected memory cells is further compounded by the cumulative effect of unselected memory cells on a bitline that has a selected cell (e.g. cell 314 on bitline 308j). For example, if bitline 308j has 256 memory cells, one of which is selected, the cumulative leakage of 255 poorly deselected memory cells will deflect the bitline 308j potential, thereby reducing the available sense signal. A similar requirement to adequately reverse bias the unselected memory cells occurs with either the FET based or bipolar based switching element shown in FIGS. 5 and 6 respectively. In the case of a FET-based switching element, the gate to source potential must be well below the FET threshold including any body effects. In the case of the bipolar-based switching element the base-emitter diode must be adequately reverse biased to prevent conduction.

An example of voltage bias conditions and current conditions for diode-based PCM devices as shown in FIGS. 10, 11 and 12 are summarized in Table 2 (Kwang-Jin Lee et al., “A 90 nm 1.8 V 512 Mb Diode-Switch PRAM With 266 MB/s Read Throughput,” IEEE J Solid-State Circuits, vol. 43, no. 1, pp. 150-162, January 2008). All voltage and current values are examples for the shown embodiments. Other values consistent with a process technology and cell characteristic are within the scope of the invention.

TABLE 2
Voltage and Current Conditions for a diode-based PCM

| | Reset Write | Set Write | Read |
|---|---|---|---|
| Unselected W/L | VDD + 2 V | VDD + 2 V | VDD + 1 V |
| Selected W/L | 0 V | 0 V | 0 V |
| Unselected B/L | Floating | Floating | Floating |
| Selected B/L | I_Reset | I_Set | I_Read |

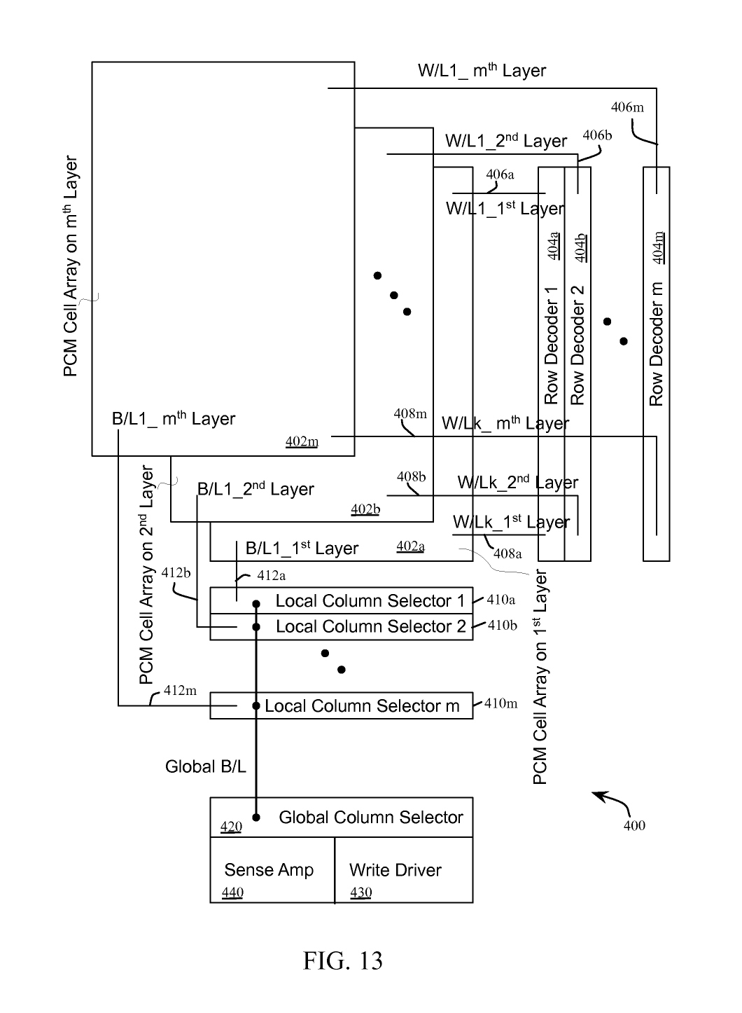

FIG. 13 depicts a three-dimensional stacked PCM architecture according to an embodiment of the present invention. Referring to FIG. 13, a three-dimensional (3-D) stacked PCM architecture 400 includes PCM cell arrays 402a through 402m that are on a stack of semiconductor layers with one PCM cell array on each of the layers. In the 3-D stacked PCM architecture 400, a row decoder 404a and a local column selector 410a are on the same layer as PCM cell array 402a. The row decoder 404a communicates with PCM cell array 402a through a plurality of communication paths 406a and 408a (other paths not shown for clarity). The communication paths between the row decoder 404a and the PCM cell array 402a includes wordline drivers 312a through 312k as shown in FIG. 10. In another example, the communication paths also include paths for enabling and decoding of redundant row elements. Each of the communication paths can connect the row decoder 404a directly to a wordline driver, or in other examples, the connection occurs through a voltage level translator, a voltage clamp or another intermediate device.

The local column selector 410a communicates with PCM cell array 402a through a plurality of communication paths 412a (and others not shown for clarity). The communication paths between the local column selector 410a and the PCM cell array 402a includes bitlines 308a through 308j as shown in FIG. 10. In another example, the communication paths also include paths for enabling and decoding of redundant column elements. Each of the communication paths can connect the local column selector 410a directly to a bitline, or in other examples, the connection occurs through a voltage level translator, a voltage clamp or another intermediate device.

In one embodiment of the 3-D stacked PCM architecture 400, the PCM cell arrays 402b through 402m are on semiconductor layers formed over the semiconductor layer on which PCM cell array 402a is formed. The row decoder 404a and local column decoder 410a are formed on the semiconductor layer including PCM cell array 402a. The row decoder 404a and the local column selector 410b are formed on the semiconductor layer including PCM cell array 402b. Similarly, the other row decoders and local column selectors are formed on the semiconductor layer including the PCM cell array that they communicate with. This arrangement advantageously improves the communication speed between row decoders, local column decoders and their respective PCM cell arrays.

In another embodiment, each of the row decoders, 404a through 404m and each of the local column decoders 410a through 410m are formed on the same layer as the PCM cell array 402a. The remaining PCM cell arrays 402b through 402m are formed on semiconductor layers formed after the layer including the PCM cell array 402a. This arrangement advantageously provides for PCM cell arrays 402b through 402m to be formed with different devices not supported by the fabrication of the semiconductor layer including PCM cell array 402a. For example, the PCM cell array 402a can be based on a diode-switching element or a FET switching element, with row decoders and local column decoders based on FET devices and PCM cell arrays 402b through 402m based on bipolar-switching elements. In another example, the PCM cell 402a is based on either a diode-switching element or a bipolar-switching element, the row decoders and local column decoders are based on bipolar devices and PCM cell arrays 402b through 402m are based on FET switching elements. By this method, each PCM cell array is optimized with a particular type of switching element without being constrained by available devices used by other logic circuitry formed on that semiconductor layer. In another example, each semiconductor layer is based on a different starting material. For example, with reference to FIG. 9, the layer 116a can be based on P-doped silicon and the layer 116b can be based on N-doped silicon, GaAs or another III-V compound. Furthermore, each semiconductor layer can be formed in a different fabrication module so that processing of the GST material need not occur in the same fabrication module as the fabrication of the row decoders, local column decoders an other related memory control circuitry.

In another example, each row decoder 404a through 404m and each local column selector 410a through 410m and the PCM cell array 402a is formed on a first silicon layer 116a in a product that allows field programming to configure the various devices (e.g. an FPGA or the like). The row decoders and local column decoders provide control for more memory bits that what is provided in the PCM cell array 402a, but is expanded with additional memory by adding PCM cell arrays 402b through 402m with additional fabrication steps (e.g. “post-processing”).

In another embodiment, the PCM cell arrays 402a through 402m are formed before the final layer, which includes all of the memory control circuitry, namely the row decoders 404a through 404m, the local column selectors 410a through 410m, the global column selector 420, the sense amplifier 440 and the write driver 430. This arrangement, allows a inventory to built of memory arrays, which are post-processed with control circuitry at a later stage.

In another embodiment, all of the row decoders 404a through 494m and all of the local column selectors 410a through 410m are formed on a first semiconductor layer. All the PCM cell arrays 402a through 402m are then formed on subsequent overlying semiconductor layers. This approach further reduces the plan-view area of the 3-D stacked PCM architecture 400 because each of the PCM memory arrays 402a through 402m can be configured with similar plan-view dimensions to the underlying control circuitry (e.g. row decoders and local column selectors). In another embodiment, the characteristics of the transistors, either FET or bipolar, used to form the row decoders and local column selectors are different than the FETs or bipolar devices used to form the switching elements in the PCM memory cells 314. Specifically, the transistors used in the PCM memory cells are optimized for low leakage, whereas the transistors in the row decoder and local column selectors are optimized for drive current or switching speed.

In the 3-D stacked PCM architecture 400, a global column selector 420 communicates with, and is formed on the same layer as, each of the local column selectors 410a through 410m. The write driver 430 and the sense amplifier 440 also are formed on the same layer as the global column selector 420. In other embodiments, the row decoders 404a through 404m, local column selectors 410a through 410m, global column selector 420, write driver 430 and sense amplifier 440 are formed on the same layer that is not the same layer upon which PCM cell array 402a is formed, for example the last processed layer is used in one example. In another embodiment, the row decoders 404a through 404m, and local column selectors 410a through 410m are formed on different semiconductor layers than the global column selector 420, write driver 430 and sense amplifier 440.

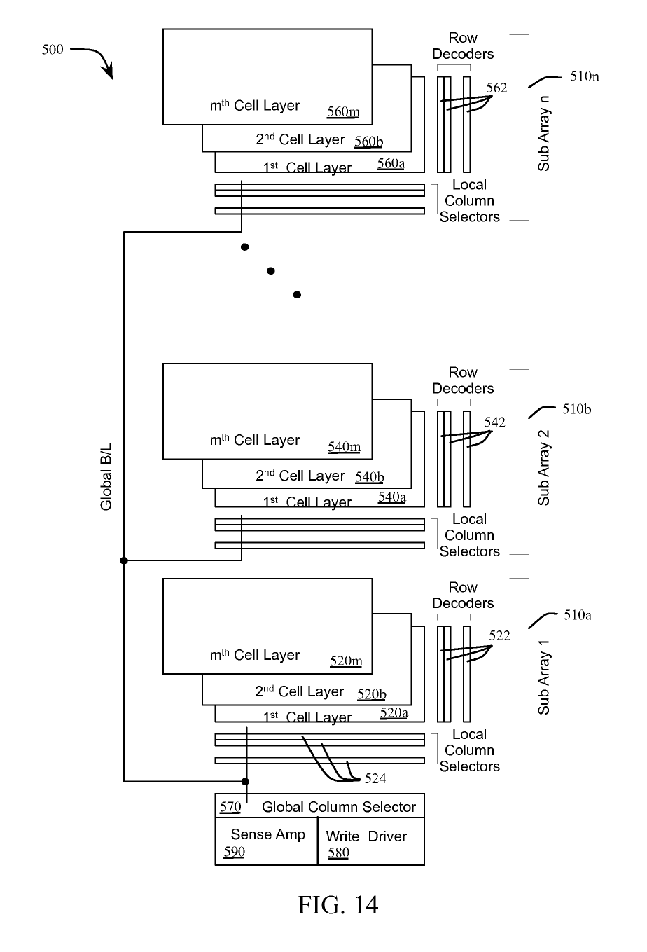

FIG. 14 shows a 3-D phase change memory architecture 500 with segmented arrays according to one embodiment. Referring to FIG. 14, a 3-D stacked PCM architecture 500 has a segmented cell array (sub-array). Each memory cell array has “n” sub-arrays. For example, one cell array includes sub-arrays 520a through 560a. Another cell array includes sub-arrays 520b through 560b. In the 3-D stacked PCM architecture 500, all row decoders 522 through 562 are on the same semiconductor layer as all of the local column selectors 524 through 564, in addition to a global column selector 570, a write driver 580 and a sense amplifier 590.

In one embodiment, all of the row decoders 522 through 562 are formed adjacent to one another on the same semiconductor layer. Advantageously, this arrangement of row decoders optimizes layout density because each row decoder is of a similar height (also called being “pitch-matched”). In one embodiment, all of the local column selectors 524 through 564 are formed side-by-side on the same layer. Advantageously, this arrangement of local column selectors optimizes layout density because each local column selector is of a similar height.

The global bit-lines run over “n” sub-arrays 510a through 510n and in one embodiment are implemented in a third metal layer. The global bit-lines connect to the local column selectors and the global column selector used with each sub-array as shown in FIG. 14. For example, each of the local column selectors 524 connect to one of the cell arrays 520a through 520m in sub-array 510a and select a group of bitlines from each cell array corresponding to a data word to be accessed for example. The output of each of the local column selectors 524 connects to the global column selector 570, which in turn selects data from one of the local column selectors 524.

Similar to the 3-D stacked PCM architecture 400 shown in FIG. 13, all of the row decoders 522 through 562, local column selectors 524 through 564, the global column selector 570, the write driver 580 and the sense amplifier 590 are formed on the same first semiconductor layer in one embodiment. The cell arrays 520a through 560a are also formed on the same first layer in one example. In another example, all of the cell arrays 520a-520m through 560a-560m are formed in layers formed over the first semiconductor layer. The various combinations of diode, FET and bipolar devices, including differing characteristics of FET devices as described for the 3-D stacked PCM architecture 400 in FIG. 13 are also envisioned for the 3-D stacked PCM architecture 500 in FIG. 14.”

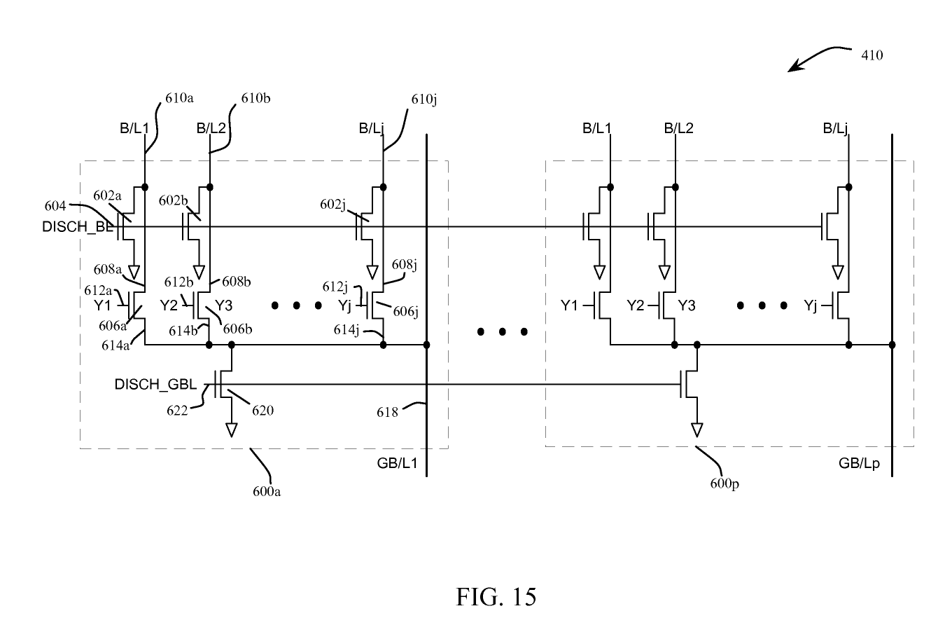

FIG. 15 shows an example of one of the local column selectors 410a-410m shown in FIG. 13, or the local column selectors 524 through 564 shown in FIG. 14. Referring to FIG. 15, the local column selector has “p” groups of local column decoders 600a through 600p, p being an integer greater than one. Each of the column decoders includes “j” NMOS bit-line discharge transistors 602a through 602j, each controlled by a bit-line discharge signal “DISCH_BL” 604. Each of the column decoders includes “j” NMOS column select transistors 606a through 606j. The drains 608a through 608j of the column select transistors 606a through 606j are connected to respective ones of bit-line 610a through 610j. The gates 612a through 612j of the column select transistors 608a through 608j are connected to respective ones of local column select lines 612a to 612j. The sources 614a through 614j of the column select transistors 606a through 606j are connected to a common global bit-line 618. The global bit-line 618 is connected to the drain of an NMOS transistor 620, the source of which is connected to the ground. The gate 622 of the NMOS transistor 620 is connected to a common global bitline discharge signal source (not shown) to provide a common global bitline discharge signal “DISCH_GBL” 622. The common global bit-line discharge signal “DISCH_GBL” 622 fed to the gate of an NMOS transistor 620 controls the discharge of the global bitline 618.

With reference to FIGS. 11 and 15, bitlines 308a, 308b and 308j correspond to the bitlines 610a, 610b and 610j. During the WRITE operation phase, when the cell 314 is being written, the bitline discharge signal “DISCH_BL” 604 and the common global bitline discharge signal “DISCH_GBL” 622 are low to deactivate the respective discharge paths. Gates 612a and 612b are low to deactivate the column select transistors 606a and 606b thereby floating bitlines 610a and 610b. Gate 612j is held high to activate the column select transistor 606j and connect the global bitline 618 to the local bitline 610j associated with the memory cell 314 (of FIG. 11) being written.

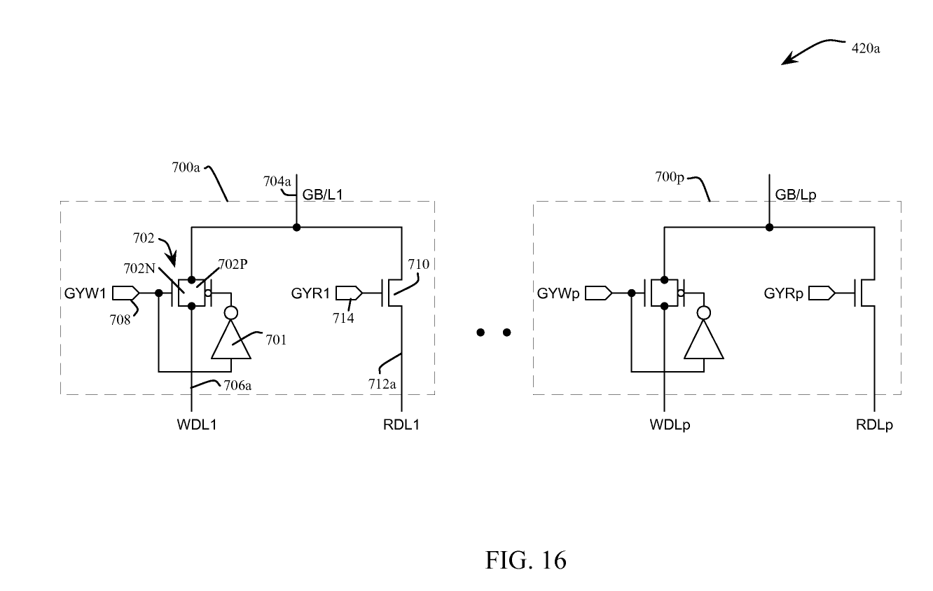

FIG. 16 shows one embodiment 420a of the global column selector 420 shown in FIG. 13. The embodiment 420a is also an example of the global column selector 570 in FIG. 14. Each global column selector has “p” groups of global column decoders 700a through 700p, “p” being an integer greater than one. Each of the global column decoders 700a though 700p operates for a respective one of the global bit lines 704 (GB/L1 to GB/Lp) connected to their local column decoders 600a through 600p shown in FIG. 15.

Each of the global column decoders 700a through 700p includes a full CMOS transmission gate 702, an inverter 701 and an NMOS transistor 710. The transmission gate 702 is formed by an NMOS transistor 702N and a PMOS transistor 702P and located between the global bit-line 704 and the write data-line 706. The gate of the NMOS transistor 702N is connected to an input 708 to which a write global column select signal “GYW1” is fed. The input 708 is connected via the inverter 701 to the gate of PMOS transistor 702P. The transfer gate 702 is controlled by write global column select signal GYW1. The NMOS transistor 710 is located between the global bit-line 704a and a read global column select line 712. The global column selector 420a is used to select one of the groups of local column selectors 600a through 600p shown in FIG. 15 and to provide selection of either a write data from write data line “WDL1” 706a or a read data from read data line “RDL1” 712a. The write data line 706a is connected to the global bit line “GB/L1” 704a through a complementary pair of PMOS and NMOS transistors (the full CMOS transmission gate 702), so that a full supply voltage is passed to the memory cell 314 (of FIG. 12) to ensure a wider margin or separation between the RESET and SET states in the memory cell 314 being written to. The read path to the read data line “RDL1” only requires a single ended device (e.g. the NMOS transistor 710 without a PMOS transistor), because the read signal can be sensed without the full supply voltage differential caused by reading the two programmed states.

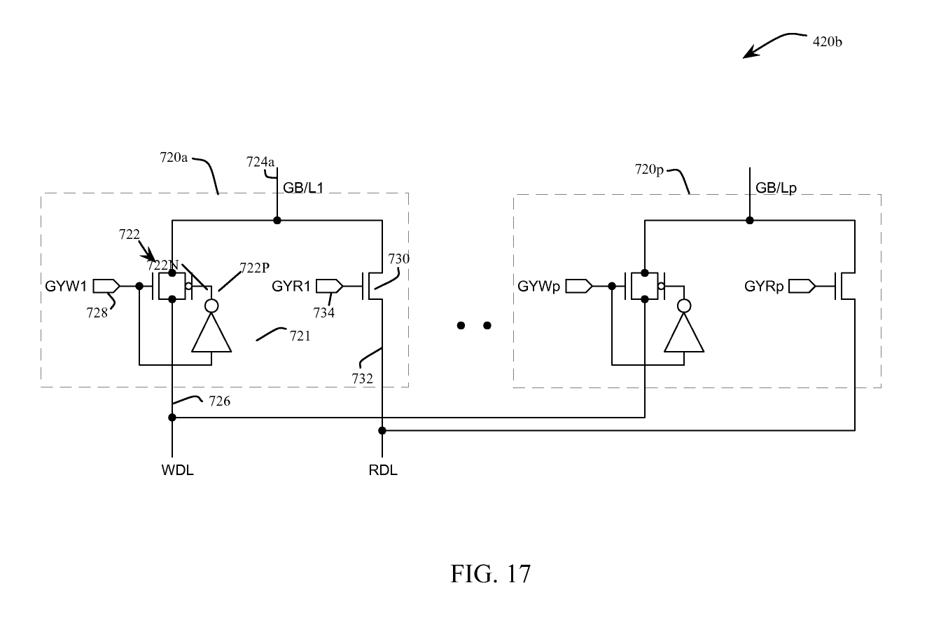

FIG. 17 shows another embodiment 420b of the global column selector 420 shown in FIG. 13. The embodiment 420b is also an example of the global column selector 570 in FIG. 14. Each global column selector has “p” groups of global column decoders 720a through 720p, each of which includes a full CMOS transmission gate 722 and an NMOS transistor 730. The global column decoders 720a through 720p share a common write data-line (WDL) 726. For example, the first global column decoder 720a includes a full CMOS transmission gate 722 between a global bit-line “GB/L1” 724a and the WDL 726. The transmission gate 722 is formed by an NMOS transistor 722N in parallel with a PMOS transistor 722P, both located between the global bit line 724a and WDL 726. The gate of NMOS transistor 722N is connected to an input 728 to which a write global column select signal “GYW1” is fed. The input 728 is connected via an inverter 721 to the gate of the PMOS transistor 722P. The transmission gate 722 is controlled by the write global column select signal GYW1. The global column decoders 720a through 720p also share a common read data-line (RDL) 732. The first global column decoder 720a includes an NMOS transistor 730 between the global bitline 724a and the common read data-line (RDL) 732. The gate of the NMOS transistor 730 is controlled by the read global column select signal GYR1. The global column selector 720a is used to select one of the groups of local column selectors 600a through 600p shown in FIG. 15 and to provide selection of either write data controlled by GYW1 728 or read data controlled by GYR1 734. In one preferred embodiment, only one of the GYW1 728 and GYR1 734 control signals are selected at one time. In another embodiment, both GYW1 728 and GYR1 734 control signals are selected at the same time to use the global column selector 420b as a data bypass useful for testing purposes to control and observe data flow independent of the functionality of the memory arrays. The purpose and benefits of the transmission gate 722 and NMOS transistor 730 in the embodiment 420a are similar to the purpose and benefits of the transmission gate 702 and the NMOS transistor 710 in the embodiment 420a. The embodiment in FIG. 17 is advantageous for architectures that share a common READ and WRITE data bus (“RDL” and “WDL”).

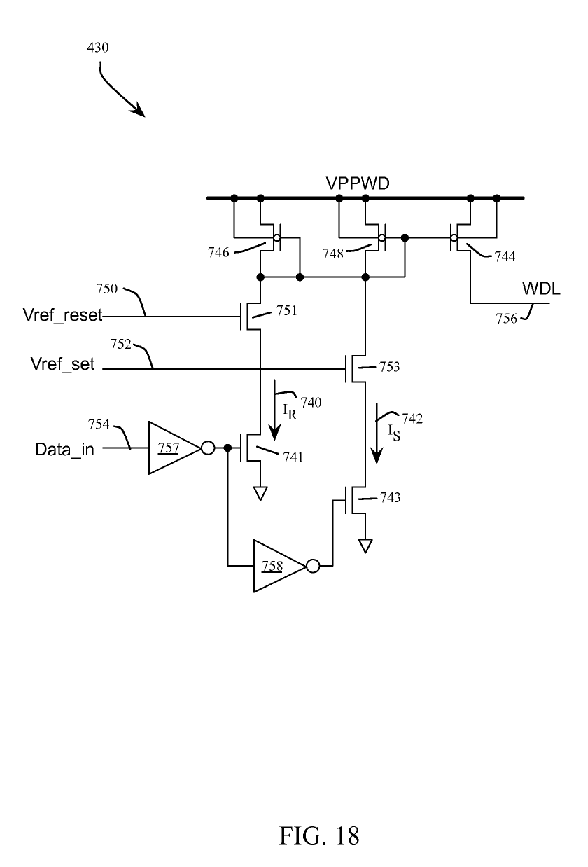

The embodiment 430 in FIG. 18 is an example of the write driver 430 shown in FIG. 13. The embodiment 430 is also an example of the write driver 580 shown in FIG. 14. Referring to FIGS. 13 and 18, in response to a data input signal 754 and control voltages 750 and 752, two currents “I_{R}” 740 and “I_{S}” 742 flow. The current 740 flows through the transistors 746, 751 and 741 and is gated by transistors 751 and 741 by two conditions. Firstly, the Vref_reset control voltage 750 must be high to enable RESET programming. Secondly, the Data_in signal 754 must be low (or at a logical “0” state as shown in Table 1). When these two conditions are met, transistors 751 and 741 are both on and current 740 is allowed to flow.

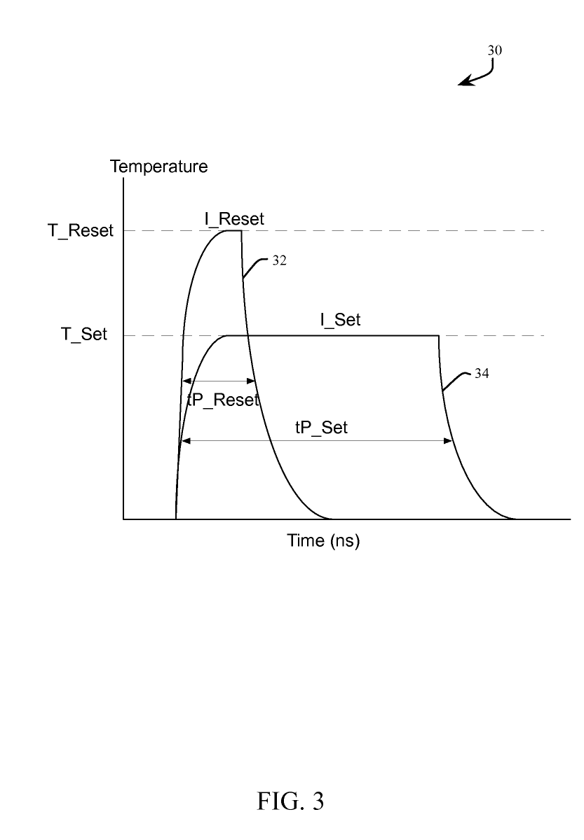

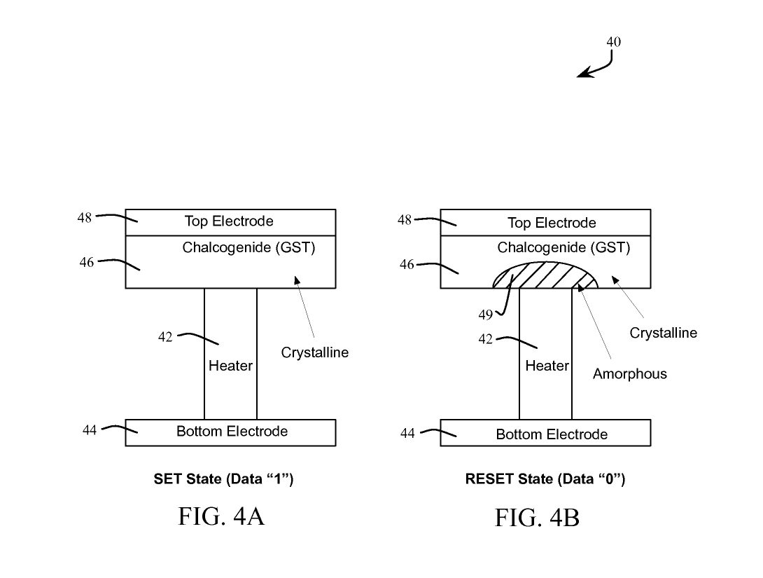

The current 742 flows through the transistors 748, 753 and 743 and is gated by transistors 753 and 743 by two conditions. Firstly, the Vref_set control voltage 752 must be high to enable SET programming. Secondly, the Data_in signal 754 must be high (or at a logical “1” state as shown in Table 1). When these two conditions are met, transistors 753 and 743 are both on and current 740 is allowed to flow. Separate control of the Vref_reset 756 and Vref_set 752 controls voltages is used because the RESET and SET programming intervals (described as the Write Pulse in Table 1) are required to properly alter the programming volume 49 shown in FIG. 4. The Data_in signal 754 controls the transistors 741 and 743 through a pair of inverters 757 and 758 respectively. Specifically, Data_in 754 is inverted by inverter 757 to turn on transistor 741 when Data_in 754 is low. Inverter 757 also buffers the transistor 741 so a plurality of write driver circuits 430 each with a transistor 741 connected in parallel do not impose an excessive capacitive load on the control signal Data_in 754, which would reduce the transition time of the Data_in 754 signal. The Data_in 754 signal is inverted by the output of inverter 757 feeding into a second inverter 758, the output of which controls the gate of transistor 743 and turns on transistor 743 in response to a high voltage on the Data_in 754 signal. With reference to Table 1 and FIG. 4, a high voltage on Data_in 754 corresponds to a logical “1” state or the SET state. A low voltage on Data_in 754 corresponds to a logical “0” state or the RESET state. A current mirror formed by PMOS transistors 746 and 744 mirrors the current 740 to WDL 756 during a RESET operation. A current mirror formed by the PMOS transistors 748 and 744 mirrors the current 742 to WDL 756 during a SET operation. The write driver 430 provides a higher current for RESET shown as I_Reset and a lower current for the SET operation shown as I_Set in FIG. 3. The magnitude of the RESET current 740 is proportional to the ratios of the length of transistors 744 and 746. Similarly, the magnitude of the SET current 742 is proportional to the ratios of the length of transistors 744 and 746.

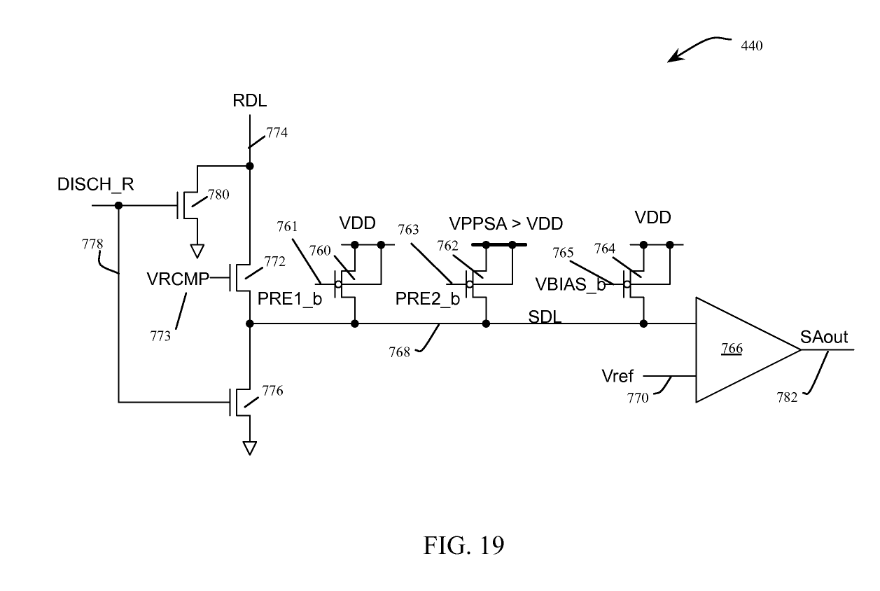

FIG. 19 shows an example of the sense amplifier 440 shown in FIG. 13. The sense amplifier 440 is also an example of the sense amplifier 590 shown in FIG. 14. The sense amplifier 440 reads data from a bitline in a memory (e.g. the PCM cell array 402a in FIG. 13). The bitline within the memory array is selected by the local column selector 410a, the global column selector 420 further selects the local column selector 410a from a plurality of local column selectors and the data passes from the PCM cell array 402a to the sense amplifier 440 on a read data line “RDL” 774 shown in FIG. 19.

With reference to FIG. 19, a PMOS bit-line precharge transistor 760 is controlled by “PRE1_b” 761 with a voltage source equal to VDD. Another PMOS bit-line precharge transistor 762 is controlled by “PRE2_b” 763 with a voltage source equal to VPPSA, where VPPSA is typically greater than VDD. A PMOS bit-line bias transistor 764 is controlled by “VBIAS_b” 765 with a voltage equal to VDD. The drains of the PMOS transistors 760, 762 and 764 are commonly connected to a sensing data-line “SDL” 768. A differential voltage amplifier 766 has two inputs one of which is connected to SDL 768 and the other of which is connected to a reference voltage “Vref” 770. An NMOS voltage clamp transistor 772 is between RDL 774 and the SDL 768 and is controlled by “VRCMP” 773. An NMOS transistor 776 is controlled by “DISCH_R” 778 for SDL 768 discharge. An NMOS transistor 780 is controlled by “DISCH_R” 778 to discharge RDL 774. The discharge transistors 776 and 780 discharge the SDL 768 and RDL 774, respectively, in preparation for a READ operation. In one example, the NMOS transistor 780 is larger than the NMOS transistor 776 to discharge RDL 774 at the same rate as SDL 768, RDL 774 having a higher capacitive loading than SDL 768.

The two precharge transistors 760 and 762 provide for a more gradual precharge rate on the bitlines. Advantageously, the two slope precharging approach reduces the burden on a charge pump used to supply the VPPSA voltage. VPPSA is boosted from VDD with a charge pump. In one embodiment, VPPSA is VDD+2V. Charge pumps have limited current sourcing ability for a given area. The two stage precharge scheme first uses PRE1b_761 to bring SDL 768 from 0V to VDD by sourcing current directly from VDD. The second stage then uses PRE2_b 763, which charges SDL 768 from VDD to VPPSA using current supplied by the VPPSA charge pump. By precharging SDL to VPPSA, adequate read voltage margin for diode based PCM cells is ensured.

The bias transistor 764 provides a load current equal to the current sunk by the selected memory cell 314 (of FIG. 12), excluding parasitic currents and converts the current drawn from the selected memory cell into a voltage on SDL 768. The amplifier 766 then compares the developed voltage on SDL 768 against the reference voltage “Vref” 770, and drives a sense amplifier output “SAout” 782 high if SDL 768 exceeds the reference voltage Vref 770. Referring to FIGS. 4, 12 and 19, if the memory cell 314 is programmed to the RESET state, amorphous material 49 will be present, which will result in higher resistance between the top electrode 48 and the bottom electrode 44, compared to the SET state. Higher resistance will result in a larger voltage drop across the memory cell 314 and consequently a higher voltage at SDL 768 is sensed than when a SET state is sensed.

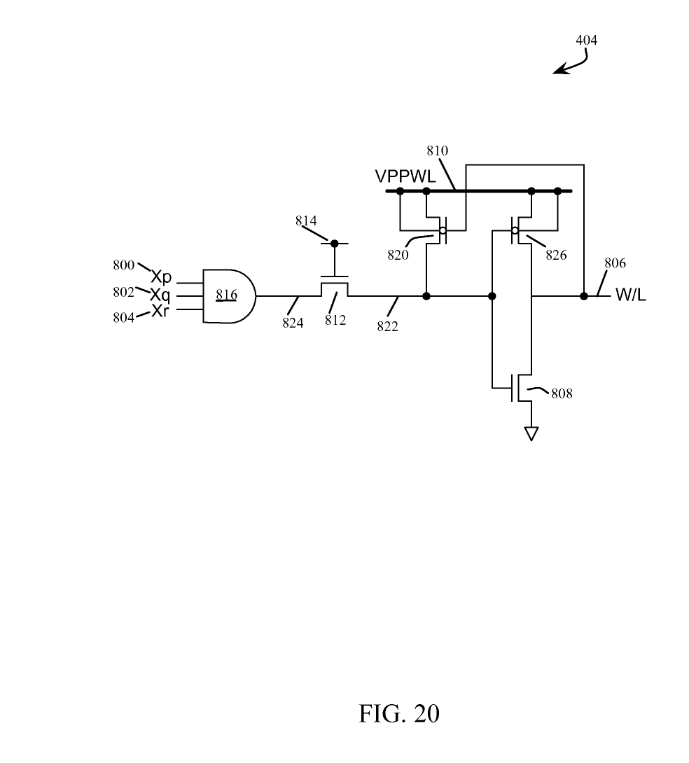

FIG. 20 shows an embodiment 404 of any of the row decoders 404a through 404m shown in FIG. 13. The embodiment 404 also is an example of any of the row decoders 522 through 562 shown in FIG. 14. The row decoder 404 is enabled by pre-row-decoder outputs Xp 800, Xq 802 and Xr 804, which control an AND gate 816. The output of the row decoder 404 is connected to a corresponding wordline “W/L” 806, which connects to a wordline of a diode-based switching element 312b as shown in FIGS. 11 and 12. W/L 806 is driven to 0V when selected and to VPPWL 810 when unselected. In another embodiment, the row decoder 404 is adapted for a FET-based or bipolar-based switching element by replacing the AND gate 816 with a NAND gate.

Referring to the row decoder shown in FIG. 20, when each of Xp 800, Xq 802 and Xr 804 are in the high state, the output of AND gate 816 outputs the high state, turning on transistor 808, which pulls W/L 806 low. Accordingly, when Xp 800, Xq 802 and Xr 804 are in the high state, then W/L 806 is selected. If any one of Xp 800, Xq 802 or Xr 804 are low, then AND gate 816 outputs the low state and transistor 826 pulls W/L 806 high or to the unselected state. The value of VPPWL 810 is VDD+2V during a WRITE operation and VDD+1V during a READ operation as previously discussed in FIGS. 11 and 12 and Table 2. The row decoder 404 has a clamping transistor 812 controlled by voltage 814 to prevent VPPWL 810 from sourcing excessive voltage back to the NAND gate 816. The clamping transistor operates by “pinching off” the current flow from 822 to 824 when the voltage on 822 (e.g. VPPWL) equals the voltage 814 minus the threshold voltage of transistor 812. The row decoder 404 also uses a pull-up FET 820 activated when W/L 806 is low, or selected, thereby ensuring that selected wordlines (e.g. 312a, and 312c through 312k in FIGS. 11 and 12) will remain selected in the presence of noise coupling. In another embodiment of a row decoder for a diode-based memory, the AND gate 816 is replaced with a NAND gate and an inversion stage is added between W/L 806 and the wordline 312b, to enable the pull-up transistor 820 when the row decoder is unselected. This ensures that unselected wordlines are not activated by noise coupling from other sources, for example noise from selecting 312b.

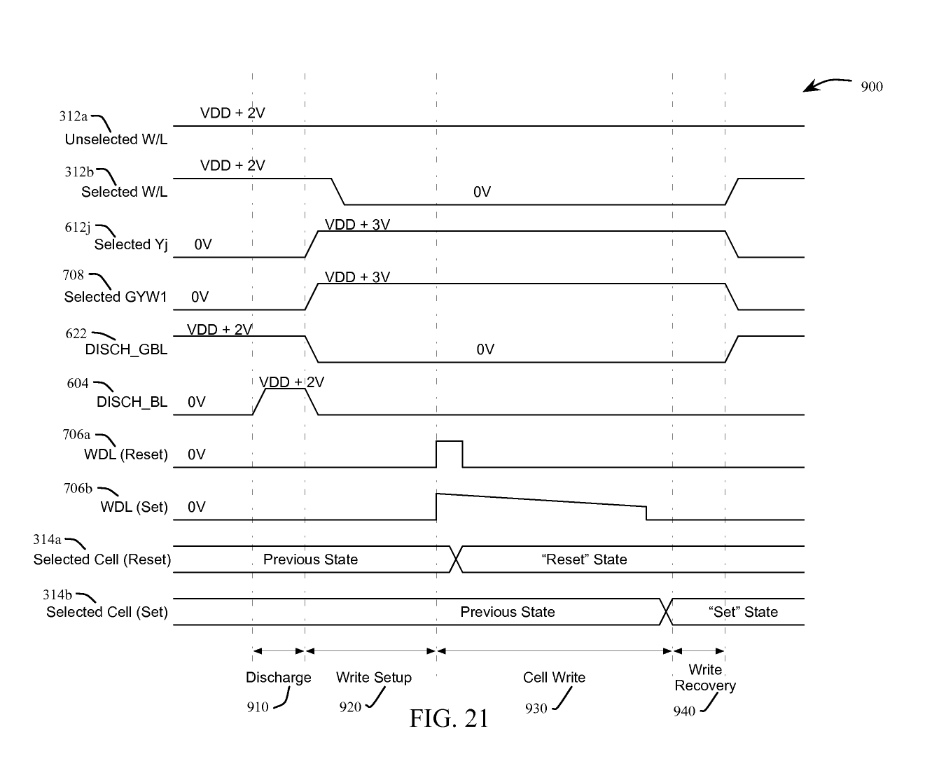

FIG. 21 shows a WRITE-operation timing diagram including four phases, namely “Discharge” 910, “Write Setup” 920, “Cell Write” 930 and “Write Recovery” 940. During the Discharge phase 910, local bitlines and global bitlines are discharged to 0V. This is accomplished by raising the DISCH_BL 604 and DISCH_GBL 622 signals to VDD+2V. Raising DISCH_BL 604 and DISCH_GBL 622 to a voltage greater than VDD provides more drive current to discharge the bitline and global bitline, respectively. In another embodiment, DISCH_BL 604 and DISCH_GBL 622 are only raised to VDD and the Discharge phase 910 is extended for longer discharge time.

Referring to FIGS. 11, 15, 20 and 21, during the Discharge phase 910, the wordlines (e.g., wordlines 312a and 312c through 312k) are deselected by applying VDD+2V. Although the wordlines need only be raised to approximately one diode threshold above the bitline (e.g., the bitline 308j) potential to prevent the diode-based memory cells from conducting, raising the wordlines to VDD+2V ensures that the memory cells 314 shown in FIG. 11 will not conduct current while the bitlines are discharging. The bitlines (610a through 610j in FIG. 15) and the global bitlines (618 in FIG. 15) are also discharged by applying VDD+2V to DISHC_BL 604 and DISCH_GBL 622 respectively.

Referring to FIGS. 11, 15, 16, 18 and 21, during the Write Setup phase 920, the local bitlines and global bitlines are allowed to “float” by deactivating DISCH_BL 604 and DISCH_GBL 622, respectively. A floating bitline means the bitline potential is not driven by a low impedance source (e.g. a driver) but can significantly maintain the previously potential with the parasitic capacitance of the bitline. The write driver output WDL 756 shown in FIG. 18 is connected to a selected wordline (e.g. 312b in FIG. 11) through an inverter (not shown) to select the diode-based memory cell 314 to be written to. The bitline 308j (shown as 610j in FIG. 15) is selected by selecting Yj 612j in a local column selector and GYW1 708 in a global column selector. The voltages applied to Yj 612j and GYW1 708 are VDD+3V to ensure the full voltage range (e.g. VPPWD) of the WDL signal 756 (shown in FIG. 18) can pass from the write driver 430 to the memory cell 314.

Referring to FIGS. 3, 4, 11, 16, 18 and 21, during the Cell Write phase 930, the cell 314 is written to the RESET state by fast quenching or to the SET state by slow quenching, respectively. The write driver 430 provides the proper write current in accordance with the Data_in signal 754 and control signals 750 and 752 shown in FIG. 18. To write a RESET state to the memory cell 314 a short pulse is provided, shown as 706a in FIGS. 21 and 32 in FIG. 3. To write a SET state to the memory cell 314 a longer pulse is provided, shown as 706b in FIGS. 21 and 34 in FIG. 3.

During the Write Recovery phase 940, the Chalcogenide compound 46 in FIG. 4 is given additional time to crystallize and cool. Following the Write Recovery phase 940, the selected wordline 312b and the global bit-line discharge signal “DISCH_GBL return to VDD+2V. The local column select Yj 612j and global column select GYW1 708 are turned off.

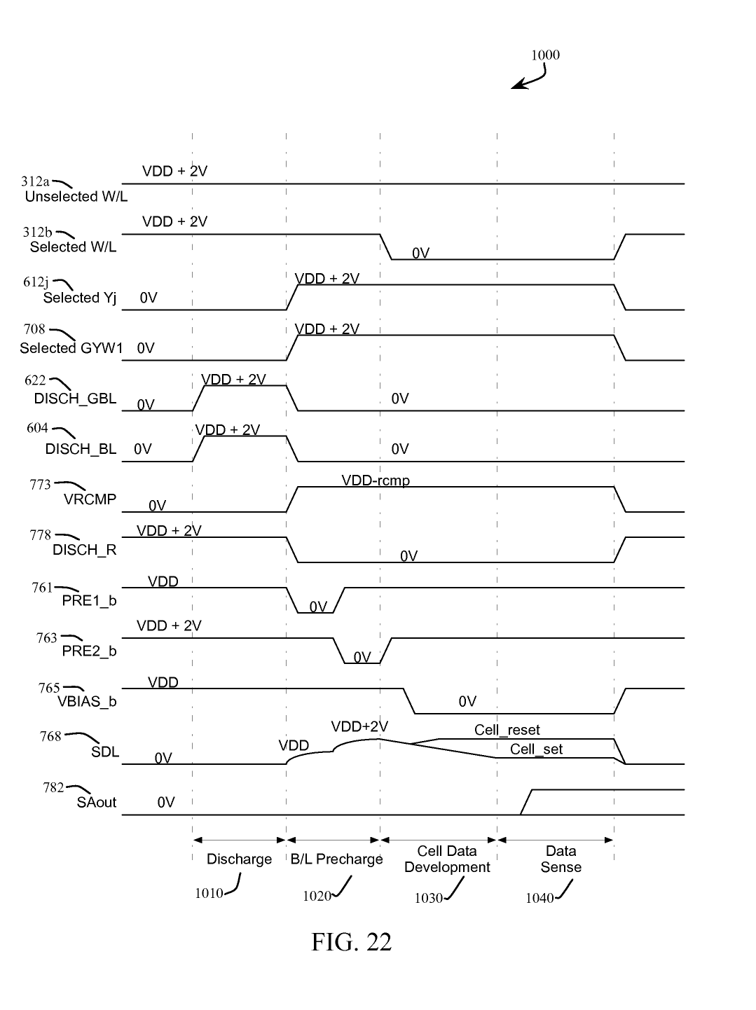

FIG. 22 shows a READ-operation timing diagram including four phases, namely “Discharge” 1010, “B/L Precharge” 1020, “Cell Data Development” 1030 and “Data Sense” 1040. During the Discharge phase 1010, the local bit-lines and global bit-lines are discharged by the DISCH_BL 604 and DISCH_GBL 622 signals, similar to the WRITE-operation shown in FIG. 21. In addition, RDL 774 and the SDL 768 signals are discharged by applying VDD+2V to the DISCH_R 778 signal shown in FIG. 19.

Referring to FIGS. 15, 16, 19 and 22, during the bitline-precharge phase 1020, the local and global column select transistors, are turned on by the selected column select line Yj 612j and the global column select line GYW1 708, respectively. VRCMP 773 (shown in FIG. 19) is set to a “VDD-rcmp” voltage level, which will cause the clamping transistor 772 to limit the voltage that can be passed from RDL 774 to SDL 768 to prevent the amplifier 766 from saturating and limiting recovery time. In one embodiment, VDD-rcmp is set to VDD+3V thereby allowing a voltage of VDD+3V less the threshold of the clamping transistor 772 to be passed from RDL 774 to SDL 768. The SDL 768 is precharged to VDD+2V with a two-step precharge operation, first to VDD (1.8V for example) and then to VDD+2V by precharge signals PRE1_b 761 and PRE2_b 763 respectively.

Referring to FIGS. 12, 19 and 33, during the Cell Development phase 1030, the selected wordline 312b is biased to 0V. The bias transistor 764 for SDL 768 is enabled (shown in FIG. 19). During this period the selected memory cell 314 will draw current and cause SDL 768 to change potential in accordance with the programmed state in the memory cell 314.

Referring to FIGS. 19 and 22, during the Data Sense phase 1040, the sense amplifier senses SDL 768 and causes SAout 782 to go high if SDL 768 exceeds the reference voltage 770. In one embodiment, the amplifier 766 latches the state of SAout 782 controlled by an additional control pin. In another embodiment, the amplifier 766 includes hysteresis so that SAout 782 will not toggle when SDL 768 is equal to Vref 770 during the cell data development phase 1030.

In the embodiments described above, the device elements and circuits may be connected directly to each other or alternatively may be indirectly connected to each other through other elements, circuits and the like without departing from the spirit or scope of the invention. Furthermore, alterations, modifications and variations within the knowledge of those skilled in the art are considered within the scope of the invention.

What is claimed is:

1. A method of fabricating a memory device comprising:
forming a stack of semiconductor layers;
forming a circuit on a layer of the stack of semiconductor layers;
forming a primary memory array on another layer of the stack of semiconductor layers different from the layer comprising the circuit; and
forming a plurality of electrical communication paths between the circuit and the primary memory array, the circuit controlling operation of the primary memory array over the electrical communication paths.

2. The method of claim 1 wherein forming the primary memory array includes forming a phase change memory.

3. The method of claim 1 wherein forming the primary memory array includes forming a phase change memory comprising a plurality of memory cells, each memory cell including a diode connected to a variable resistive element.

4. The method of claim 1 further comprising forming a secondary memory array on the layer comprising the circuit.

5. The method of claim 1 wherein forming the stack of semiconductor layers includes forming the layer comprising the circuit before forming the layer comprising the primary memory array.

6. The method of claim 1 further comprising forming a memory array on each layer of the stack of semiconductor layers.

7. The method of claim 1 further comprising forming a memory array on each layer of the stack of semiconductor layers, each layer being different from the layer including the circuit.

8. A memory device comprising:
a stack of semiconductor layers;
a circuit on a layer of the stack of semiconductor layers;
a primary memory array on another layer of the stack of semiconductor layers different from the layer comprising the circuit; and
a plurality of electrical communication paths between the circuit and the primary memory array, the circuit controlling operation of the primary memory array over the electrical communication paths.

9. The memory device of claim 8 wherein the primary memory array comprises a phase change memory.

10. The memory device of claim 8 wherein the phase change memory comprises a plurality of memory cells.

11. The memory device of claim 3 wherein each of the plurality of memory cells comprise a a diode connected to a variable resistive element.

12. The memory device of claim 8 wherein each of the plurality of memory cells comprise a field-effect transistor connected to a variable resistive element.

13. The memory device of claim 8 wherein each of the plurality of memory cells comprises a bipolar transistor connected to a variable resistive element.

14. The memory device of claim 8 wherein the layer comprising the circuit further comprises a memory array.

15. The memory device of claim 8 wherein the layer including the circuit is the first layer formed in the stack of semiconductor layers.

16. The memory device of claim 8 wherein each layer of the stack of semiconductor layers comprises a memory array.

17. The memory device of claim 8 further comprising a memory array on each layer of the stack of semiconductor layers, each layer being different from the layer including the circuit.

18. A memory device comprising:
a base semiconductor layer comprising a plurality of memory control circuits; and
a stack of semiconductor layers formed over the base semiconductor layer, each layer of the stack of semiconductor layers including a memory array in communication with one of the plurality of memory control circuits.

19. The memory device of claim 18 wherein each memory array comprises a phase change memory comprising a plurality of memory cells, each memory cell including a diode connected to a variable resistive element.

20. The memory device of claim 17 wherein each memory array is a phase change memory comprising a plurality of memory cells, each memory cell including a filed-effect transistor connected to a variable resistive element.

21. The memory device of claim 17 wherein each memory array is a phase change memory comprising a plurality of memory cells, each memory cell including a bipolar transistor connected to a variable resistive element.
